(19) United States
(12) Patent Application Publication
(10) Pub. No.: US 2006/0131010 A1
(43) Pub. Date: Jun. 22, 2006

(54) Heat dissipating assembly for a heat element

(76) Inventors: Chih-Ming Hsu, Taoyuan (TW); Chung-Cheng Lin, Taoyuan (TW); Chin-Ting Lee, Taoyuan (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/218,630

(22) Filed: Sep. 6, 2005

(30) Foreign Application Priority Data
Dec. 21, 2004 (TW) 93220548

(51) Int. Cl. H05K 7/20

(52) U.S. Cl. 165/185; 165/80.2; 361/704

(57) ABSTRACT

The present invention provides a heat dissipating assembly for a heat element comprising a board on which at least a heat source, heat conductive layer and a heat dissipating sheet are set. The heat conductive layer is formed between the heat dissipating sheet and the board by squeeze bonding, thermal fusion or ultrasonic fusion. The heat conductive layer is made up of a material possessing the properties of quick heat conduction and compressive flexibility. While the heat conductive layer is adhered by squeeze bonding, thermal fusion or ultrasonic fusion, heat is conducted by its entire surface. The present invention is able to raise the heat dissipating efficacy and draw out the heat from the heat source quickly, therefore, increases the brightness and durability of the light source.

### FIELD OF THE INVENTION

The present invention relates to a heat dissipating assembly, more particularly, to a heat dissipating assembly for a heat element possessing satisfied heat dissipating efficacy for the use of light source under high power.

### DESCRIPTION OF RELATED ART

The application of light emitting diode (LED) is very broad at the present time. By the improvement of the brightness of LED, it can now be used in various illumination applications such like headlights of vehicle peripherals, light sources for reading, big-sized back lights and the back lights of LED TV.

Because electric energy cannot transform into light energy efficiently when current passes through LED chips, there is always a temperature increase in LED chips which results in the decrease of brightness and durability of LED chips. Accordingly, there is a need of dissipating design for products with LED as light source which otherwise will be bothered by problems like decrease in brightness and short lifespan. LED package structures nowadays usually adopt metal core print circuit board (MCPCB) as heat conducting medium. Although conventional MCPCB can conduct heat, there is no medium for drawing out heat source quickly to a heat dissipating sheet. Due to the lack of efficient heat conducting means, LED fails to be used in a high density way and high power application. It is to say that the problem concerning heat dissipation of LED is a pressing subject to overcome.

Correspondingly, for overcoming said problems a heat dissipating assembly for a heat element with satisfied heat conducting efficacy is provided here after years of experiments in search of heat conducting medium.

### SUMMARY OF THE INVENTION

The primary object of the present invention is to provide a heat dissipating assembly for a heat element. In the heat dissipating assembly, a light source is set on the board. By quickly conducting the heat of a light source to a heat dissipating sheet through a heat conductive layer, the temperature of the light source is decreased efficiently and the transformation efficacy of electric energy is highly improved, which increases the brightness and durability of LED.

According to the present invention, the heat dissipating assembly for a heat element comprises a board and on the upper surface of the board at least one light source is set while below the under surface of the board a heat conductive layer is set and, furthermore, there is a heat dissipating sheet set the below the under surface of the heat conductive layer.

In the following embodiments the objects, features, advantages and the efficacy of the present invention will be become more understandable from the description taken in connection with the accompanying drawings in which preferred embodiment of the present invention are show.

### DETAILED DESCRIPTION OF THE PREFERRED EMBODIMENT

The present invention relates to a heat dissipating assembly for a heat element which as shown in FIG. 1 and FIG. 2. The heat dissipating assembly comprises a board 10, a heat conductive layer 12, a heat dissipating sheet 14 and a heat source 16 which are combined by squeezing bonding or fusing adhesion. Said heat source 16 is light emitting diode (LED) or is made up of heat generating electronic elements. On the board 10 a plurality of heat sources 16 are set and the heat conductive layer 12 is set under the board 10 and above the heat dissipating sheet 14. The material of the heat conductive layer is chosen from graphite or carbon fiber. The material of the board 10 and the heat dissipating sheet are selected from the group consisting of ceramic, copper, aluminum and aluminum-magnesium alloy. As shown in FIG. 1, the heat dissipating assembly for a heat element is form by a tight squeeze bonding of the board 10, the heat conductive layer 12 and the heat dissipating sheet 14. FIG. 2 illustrates the whole surface of the insulating metallic coating 20 on the heat conductive layer 12 is tightly combined with the board 10 and the heat dissipating sheet 14 by means of fusion of alloy with high temperature reflow oven or ultrasonic resonance, wherein the metallic coating 20 is made from a chemical deposition, evaporation or galvanization process.

While the heat source 16 is on and shining, heat is generated because the energy loss of the transformation of electric energy into light energy. The heat is absorbed by the board 10 first and then the heat conductive layer 12 would transmit it to the heat dissipating sheet 14 quickly, which enable the heat to be transpired into the air by the heat dissipating sheet 14 and the heat source 16.

Through the conduction of heat from the heat source 16 by the heat conductive layer 12 and the dissipation of heat from the heat dissipating sheet 14 and the heat source 16, the present invention could efficiently lower down the temperature of the heat source 16 and increase the brightness of the heat source 16 and its durability.

While the present invention has been described with reference to the illustrative embodiment, this description is not intended to be construed in a limited sense. Various modifications of the illustrative embodiment of the invention, such as the modification and variation on the structure, shape, characteristic or essence of the present invention will be apparent to those skilled in the art and fall within the scope of the invention.

### BRIEF DESCRIPTION OF THE DRAWINGS

FIG. 1 is a cross-sectional view of the heat dissipating assembly for a heat element formed by squeeze bonding according to the present invention.

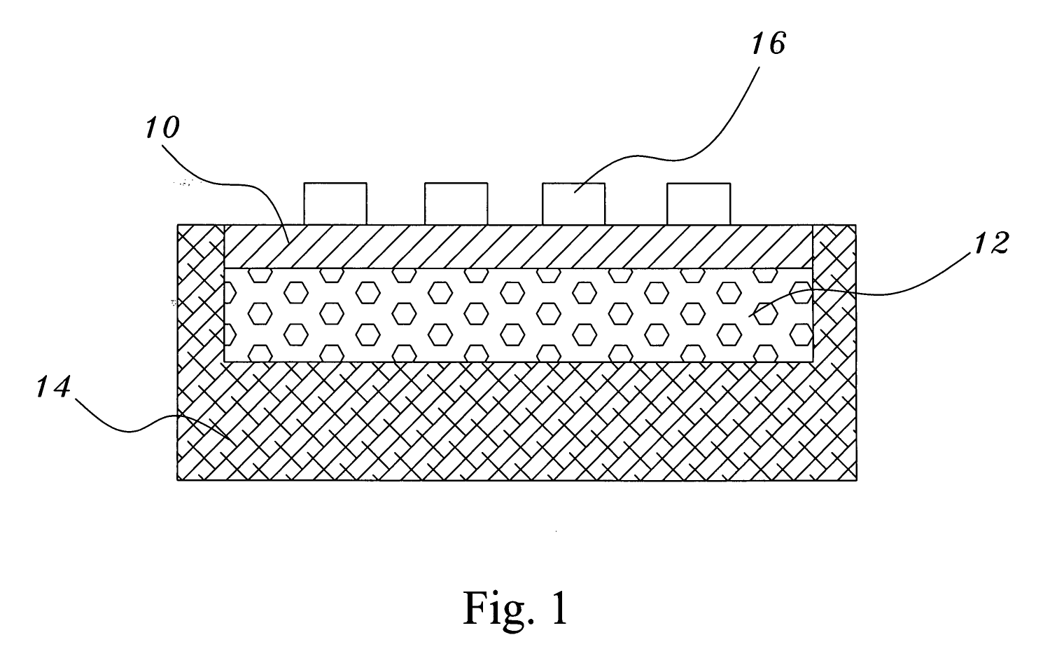

FIG. 2 is a cross-sectional view of the heat dissipating assembly for a heat element formed by thermal fusion and ultrasonic fusion according to the present invention.

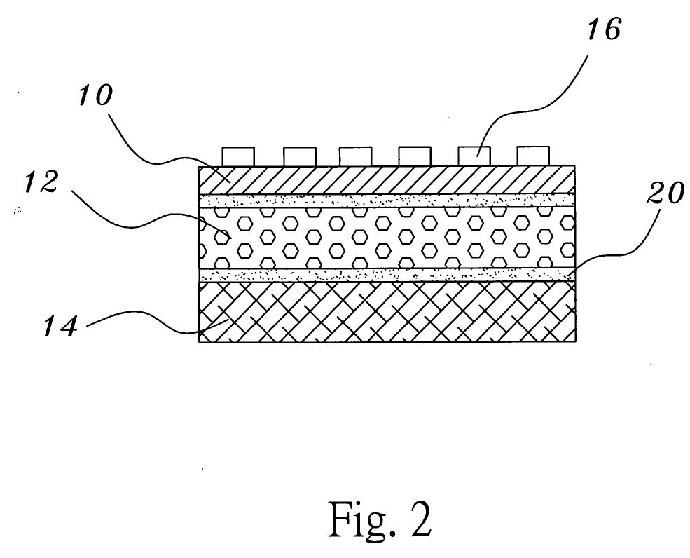

What is claimed is:

1. A heat dissipating assembly for a heat element, comprising:
a board set with at least one heat source on its upper surface and a heat conductive layer below its under surface; and
a heat dissipating sheet set at the under surface of said heat conductive layer.

2. The heat dissipating assembly for a heat element of claim 1, wherein the heat source is light emitting diode (LED) or is made up of heat generating electronic elements.

3. The heat dissipating assembly for a heat element of claim 1, wherein the material of the board is selected from ceramic, copper, aluminum or aluminum-magnesium alloy.

4. The heat dissipating assembly for a heat element of claim 1, wherein the material of the heat conductive layer is selected from graphite or carbon fiber.

5. The heat dissipating assembly for a heat element of claim 1, wherein the board, the heat conductive layer and the heat dissipating is combined by squeeze bonding or fusing adhesion with surface coating on the heat conductive layer.

6. The heat dissipating assembly for a heat element of claim 1, wherein the heat conductive layer is processed by chemical deposition, evaporation or galvanization endowing it with insulation or metallic coating on the surface.

7. The heat dissipating assembly for a heat element of claim 1, wherein the material of the heat dissipating sheet is selected from cooper, aluminum, aluminum-magnesium alloy or iron.

8. The heat dissipating assembly for a heat element of claim 1, wherein the surface of the heat conductive layer is a rugged or smooth surface.
